(19) United States
(12) Patent Application Publication
(10) Pub. No.: US 2025/0031511 A1
(43) Pub. Date: Jan. 23, 2025

(54) LIGHT-EMITTING ELEMENT, DISPLAY DEVICE, AND PRODUCTION METHOD FOR LIGHT-EMITTING ELEMENT

(71) Applicant: SHARP DISPLA TECHNOLOGY CORPORATION, Kameyama City, Mie (JP)

(72) Inventors: Masakazu SHIBASAKI, Kameyama City, Mie (JP); Masanobu MIZUSAKI, Kameyama City, Mie (JP)

(21) Appl. No.: 18/713,618

(22) PCT Filed: Jan. 25, 2022
(86) PCT No.: PCT/JP2022/002593

§ 371 Date: May 24, 2024

(51) Int. Cl. H01L 27/15

(52) U.S. Cl. CPC H01L 27/156

(57) ABSTRACT

A difference between the height of a highest point of a first protruding portion and the height of a lowest point of the first protruding portion in a film thickness direction of a reflective electrode is in a range from 0.4 μm to 1 μm.

### TECHNICAL FIELD

The disclosure relates to a light-emitting element, a display device, and a method for manufacturing a light-emitting element.

### BACKGROUND ART

Light extraction efficiency to the outside is known about 20% in an organic light-emitting diode (OLED) display device, a quantum dot light emitting diode (QLED) display device and the like, and is expected to be improved.

### CITATION LIST

### Patent Literature

PTL 1: WO 2016/084727

PTL 2: JP 2003-51389 A

### SUMMARY

### Technical Problem

In the related art, light is absorbed by a reflective electrode formed on an insulating film made of an organic material due to the influence of propagation of light through a substrate, evanescent waves, surface plasmons, and the like. As a result, in the related art, there arises a problem that light extraction efficiency to the outside is low.

In order to solve the problem of the low extraction efficiency to the outside, the above-cited patent literature proposes techniques of forming periodic irregularities on an electrode surface by forming a trench and forming an electrode on the trench, periodically patterning a transparent conductive film, and the like.

In the above-cited patent literature, it is proposed to perform photolithography as a technique of forming those irregularities. However, in order to perform photolithography, a dedicated mask, an optical exposure process, and a cleaning process are required, and therefore the process of fabricating a light-emitting element becomes complicated. Other forming techniques are not described in detail.

### Solution to Problem

A light-emitting element according to an aspect of the disclosure is a light-emitting element including a thin film transistor layer and a light-emitting element layer that are layered in this order. In the thin film transistor layer, a thin film transistor and an insulating film formed of an organic material are layered in this order. In the light-emitting element layer, a reflective electrode electrically connected to the thin film transistor and having light reflectivity, a light-emitting layer, and an electrode having optical transparency are layered in this order. The reflective electrode is provided on the insulating film, and a first protruding portion is formed on a surface on the light-emitting layer side of the reflective electrode. A difference between a height of the highest point of the first protruding portion and a height of the lowest point of the first protruding portion is in a range from 0.4 μm to 1 μm in a film thickness direction of the reflective electrode. A display device according to an aspect of the disclosure includes the above-described light-emitting element.

A method for manufacturing a light-emitting element according to an aspect of the disclosure includes: forming an insulating film by baking a polymer material; forming a reflective electrode on the insulating film; baking the reflective electrode; and forming a protruding portion having a height in a range from 0.4 μm to 1 μm at least on a surface of the reflective electrode on the opposite side to the insulating film by collectively baking the insulating film and the reflective electrode under vacuum.

### Advantageous Effects of Disclosure

According to an aspect of the disclosure, it is possible to achieve a display device having a high light extraction efficiency to the outside.

### BRIEF DESCRIPTION OF DRAWINGS

FIG. 1 is a cross-sectional view illustrating a schematic configuration of a light-emitting element according to a first embodiment of the disclosure.

FIG. 2 is a cross-sectional view illustrating a configuration example of a reflective electrode.

FIG. 3 is a diagram illustrating a method for manufacturing a light-emitting element according to the first embodiment of the disclosure.

FIG. 4 is a table summarizing a film thickness and a refractive index of each layer of the light-emitting element manufactured by the method illustrated in FIG. 3.

FIG. 5 is a diagram depicting the composition of polyimide used in a second process of FIG. 3 in the manufacture of each of a light-emitting element according to Example, a light-emitting element according to Comparative Example 1, a light-emitting element according to Comparative Example 2, and a light-emitting element according to Comparative Example 3.

FIG. 6 is a table depicting a relationship between the light-emitting element according to Example, the light-emitting element according to Comparative Example 1, the light-emitting element according to Comparative Example 2 and the light-emitting element according to Comparative Example 3, and their light-emission characteristics.

FIG. 7 is a diagram describing a chemical bond between silver contained in a reflective electrode and polyimide constituting an insulating film in the light-emitting element according to Example.

FIG. 8 is a diagram exemplifying a preferable composition of polyimide used in the second process of FIG. 3.

FIG. 9 is a table depicting a relationship between a light-emitting element according to Comparative Example 4 and a light-emitting element according to Comparative Example 5, and their light-emission characteristics.

FIG. 10 is a cross-sectional view illustrating a schematic configuration of a light-emitting element according to a second embodiment of the disclosure.

FIG. 11 is a cross-sectional view illustrating a configuration of a charge generation layer.

FIG. 12 is a diagram for comparing traveling paths of light in the light-emitting element according to the second embodiment of the disclosure, light in a light-emitting element according to Comparative Example 7, and light in a light-emitting element according to Comparative Example 8.

FIG. 13 is a table summarizing a film thickness and a refractive index of each layer of the light-emitting element according to the second embodiment of the disclosure.

FIG. 14 is a table depicting a relationship between the light-emitting element according to the second embodiment of the disclosure, the light-emitting element according to Comparative Example 7 and the light-emitting element according to Comparative Example 8, and their light-emission characteristics.

FIG. 15 is a block diagram illustrating a schematic configuration of a display device according to a third embodiment of the disclosure.

FIG. 16 provides a plan view and a bird's-eye view depicting a configuration example of a reflective electrode.

### DESCRIPTION OF EMBODIMENTS

Embodiments of the disclosure will be described below. Note that, for convenience of description, members having the same functions as the members described earlier may be denoted by the same reference numerals and signs, and the description thereof will not be repeated.

### Results of Studies on Problems

According to one aspect of the disclosure, it is possible to form irregularities on an electrode or the like without performing photolithography. That is, the inventors have found that an object of improving the light extraction efficiency to the outside can be accomplished by a technique simpler than photolithography.

In a tandem light-emitting element, a thin film layer of an inorganic compound, more specifically, a thin film layer of an inorganic compound of lithium, ytterbium, or the like can be used as a charge generating layer. The inventors have found that the light extraction efficiency to the outside can also be effectively improved by forming irregularities in this layer as in the case of the electrode.

### First Embodiment

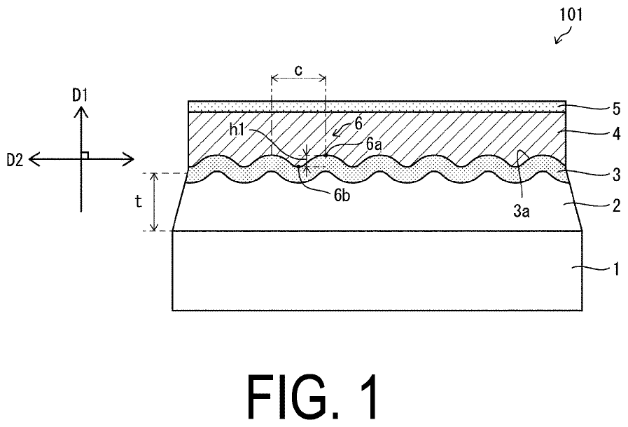

FIG. 1 is a cross-sectional view illustrating a schematic configuration of a light-emitting element 101 according to a first embodiment of the disclosure. The light-emitting element 101 includes a thin film transistor (TFT) substrate 1, an insulating film 2, a reflective electrode 3, an electroluminescence (EL) layer 4, and a translucent electrode (penetrability electrode, electrode having optical transparency) 5. The TFT substrate 1, the insulating film 2, the reflective electrode 3, the EL layer 4, and the translucent electrode 5 are layered in this order.

The insulating film 2 is formed of an organic material. The reflective electrode 3 is formed on the insulating film 2. The reflective electrode 3 is an electrode having light reflectivity. The translucent electrode 5 is an electrode having optical transparency and light reflectivity.

The EL layer 4 includes a light-emitting layer. The light-emitting layer emits light by a current flowing between the reflective electrode 3 and the translucent electrode 5. Examples of the light-emitting layer include an OLED and a QLED. The EL layer 4 may include at least one of a hole injection layer, a hole transport layer, an electron blocking layer, a hole blocking layer, an electron transport layer, or an electron injection layer as needed. The reflective electrode 3 is an anode electrode and the translucent electrode 5 is a cathode electrode. The structure of the EL layer 4 may be changed as appropriate in such a manner that the reflective electrode 3 serves as a cathode electrode and the translucent electrode 5 serves as an anode electrode. The penetrability electrode is only required to have optical transparency, is not limited to the translucent electrode 5, and may be a light-transmissive electrode having optical transparency and having no light reflectivity.

A first protruding portion 6 is formed on the reflective electrode 3. The first protruding portion 6 is formed at least on a surface 3a of the reflective electrode 3 on the opposite side to the insulating film 2 in a view of the cross section (the face illustrated in FIG. 1) of the insulating film 2 and the reflective electrode 3. A height h1 of the first protruding portion 6 is in a range from 0.4 μm to 1 μm. As illustrated in FIG. 1, the height h1 of the first protruding portion 6 is defined by a difference between the height of a highest point 6a of the first protruding portion 6 and the height of a lowest point 6b of the first protruding portion 6 in a film thickness direction D1 of the reflective electrode 3.

According to the light-emitting element 101, it is possible to reduce the influence of propagation of light through the substrate, evanescent waves, surface plasmons, and the like by the first protruding portion 6. This makes it possible to achieve a display device having a high light extraction efficiency to the outside by using the light-emitting element 101.

In the light-emitting element 101, a plurality of the first protruding portions 6 are periodically provided along a direction D2 perpendicular to the film thickness direction D1 of the reflective electrodes 3. A period c of the plurality of first protruding portions 6 is preferably in a range from 6 μm to 8 μm in the direction D2.

In the light-emitting element 101, a film thickness t of the insulating film 2 is preferably in a range from 1 μm to 3 μm. The insulating film 2 is preferably made of a polymer material containing at least one of polyimide, polyamide or polyamic acid, and the polymer material is preferably made of only one of polyimide, polyamide, and polyamic acid. The glass transition point of the polymer material is preferably in a range from 110° C. to 210° C., and more preferably in a range from 180° C. to 205° C.

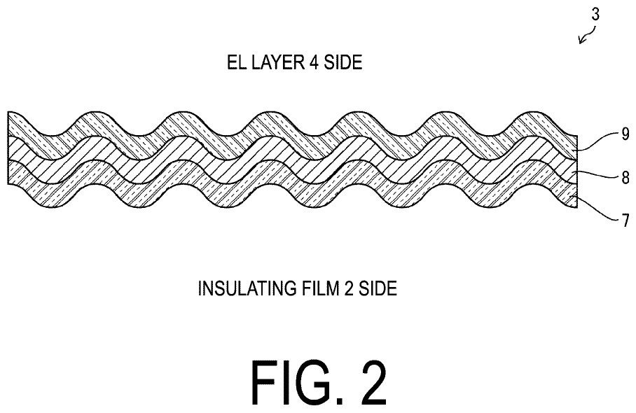

FIG. 2 is a cross-sectional view illustrating a configuration example of the reflective electrode 3. The reflective electrode 3 preferably has a layered structure of a first transparent material 7, an opaque material 8, and a second transparent material 9. The opaque material 8 preferably contains at least one of aluminum, silver, or magnesium. At least one of the first transparent material 7 and the second transparent material 9 preferably contains indium tin oxide (ITO).

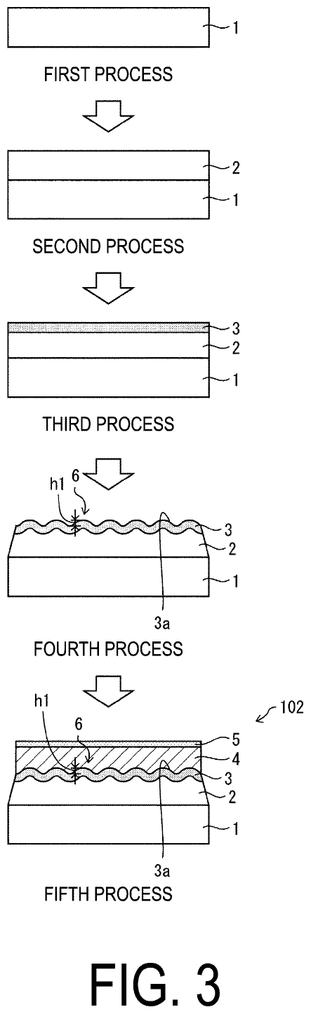

FIG. 3 is a diagram illustrating a method for manufacturing a light-emitting element 102 according to the first embodiment of the disclosure. The method for manufacturing the light-emitting element 102 can be roughly divided into a first process to a fifth process. Hereinafter, each of the first to fifth processes will be described.

The first process is a process of preparing the TFT substrate 1. In the first process, a substrate whose base material was glass was used as the TFT substrate 1.

The second process is a process of forming the insulating film 2 by baking a polymer material. In the second process, polyimide (glass transition point: 200° C.) was used as the polymer material. In the second process, the polyimide was applied to have a thickness of 1 μm on the TFT substrate 1 by spin coating. In the second process, the polyimide applied to the TFT substrate 1 was post-baked at 180° C. for 30 minutes to bake the polymer material.

The third process is a process of forming the reflective electrode 3 on the insulating film 2 and baking the formed reflective electrode 3. In the third process, a first ITO (corresponding to the first transparent material 7), silver (corresponding to the opaque material 8), and a second ITO (corresponding to the second transparent material 9) were used as the materials of the reflective electrode 3. In the third process, the first ITO (10 nm in thickness), the silver (80 nm in thickness), and the second ITO (10 nm in thickness) were formed on the insulating film 2 in that order from the insulating film 2 side by sputtering. In the third process, the above-mentioned first ITO, silver, and second ITO were post-baked at 180° C. for 30 minutes to bake the reflective electrode 3.

The fourth process is a process of forming the first protruding portion 6. In the fourth process, the insulating film 2 and the reflective electrode 3 are collectively baked under vacuum to form the first protruding portion 6 having a height (the height h1 of the first protruding portion 6) in a range from 0.4 μm to 1 μm at least on the surface 3a of the reflective electrode 3 on the side opposite to the insulating film 2. In the fourth process, the insulating film 2 and the reflective electrode 3 were baked under vacuum at 200° C. for 180 minutes to form the first protruding portion 6. A mechanism by which the first protruding portion 6 is formed in the fourth process will be described later.

The fifth process is a process of forming the EL layer 4, the translucent electrode 5, and a protection film (not illustrated) for protecting the translucent electrode 5. In the fifth process, each of the EL layer 4, the translucent electrode 5, and the protection film was formed by vacuum vapor deposition. Since the materials, detailed formation methods, and the like of the EL layer 4, the translucent electrode 5, and the protection film are within the category of known techniques, detailed description thereof is omitted here.

Each of the baking of the polymer material in the second process and the baking of the reflective electrode 3 in the third process is preferably performed at a temperature lower than the glass transition point of the polymer material.

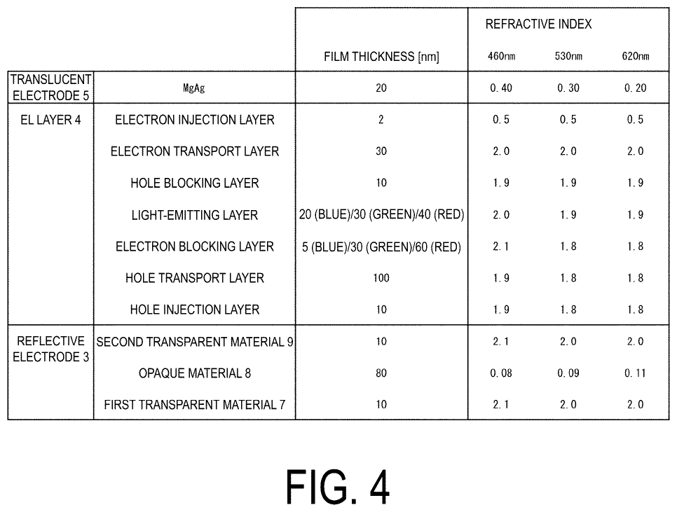

FIG. 4 is a table summarizing a film thickness and a refractive index of each layer of the light-emitting element 102. Since the film thickness of each of the light-emitting layer and the electron blocking layer of the EL layer 4 varies depending on the colors (blue, green, and red) of light emitted by the light-emitting layer, FIG. 4 specifically describes the correspondence between the colors of light emitted by the light-emitting layer and the film thicknesses. As for the refractive indices, a refractive index for 460 nm light (460 nm column), a refractive index for 530 nm light (530 nm column), and a refractive index for 620 nm light (620 nm column) are depicted.

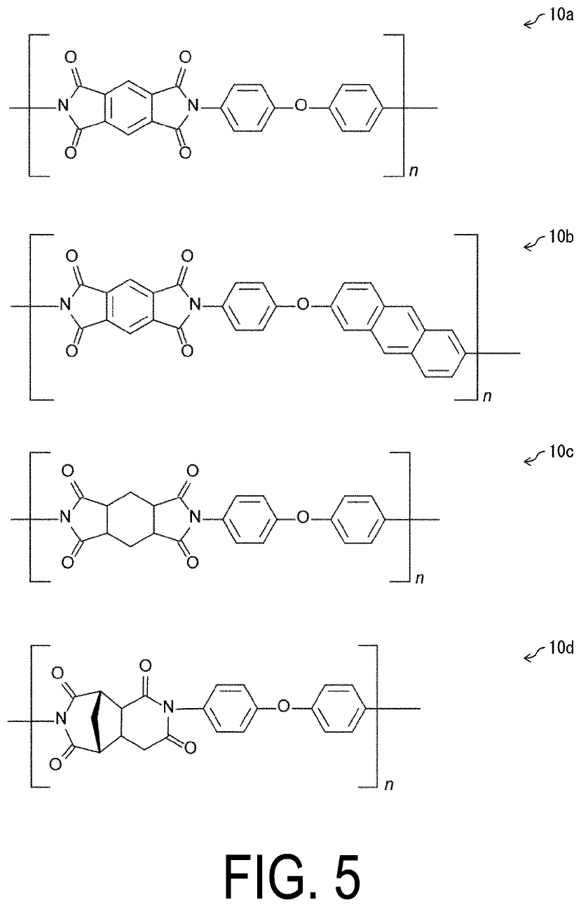

FIG. 5 is a diagram depicting the composition of polyimide used in the second process of FIG. 3 in the manufacture of each of a light-emitting element according to Example, a light-emitting element according to Comparative Example 1, a light-emitting element according to Comparative Example 2, and a light-emitting element according to Comparative Example 3. The polyimide used in the second process of FIG. 3 is, in other words, polyimide constituting the insulating film 2.

The light-emitting element according to Example is a light-emitting element manufactured by the method for manufacturing the light-emitting element 102 illustrated in FIG. 3. In the manufacture of the light-emitting element according to Example, the composition of polyimide used in the second process of FIG. 3 is represented by Chemical Formula 10a in FIG. 5.

The light-emitting element according to Comparative Example 1 is a light-emitting element manufactured by the method for manufacturing the light-emitting element 102 illustrated in FIG. 3 except that the glass transition point of polyimide used in the second process of FIG. 3 is 260° C. In the manufacture of the light-emitting element according to Comparative Example 1, the composition of the polyimide is represented by Chemical Formula 10b in FIG. 5.

The light-emitting element according to Comparative Example 2 is a light-emitting element manufactured by the method for manufacturing the light-emitting element 102 illustrated in FIG. 3. In the manufacture of the light-emitting element according to Comparative Example 2, the composition of polyimide used in the second process of FIG. 3 is represented by Chemical Formula 10c in FIG. 5.

The light-emitting element according to Comparative Example 3 is a light-emitting element manufactured by the method for manufacturing the light-emitting element 102 illustrated in FIG. 3. In the manufacture of the light-emitting element according to Comparative Example 3, the composition of polyimide used in the second process of FIG. 3 is represented by Chemical Formula 10d in FIG. 5.

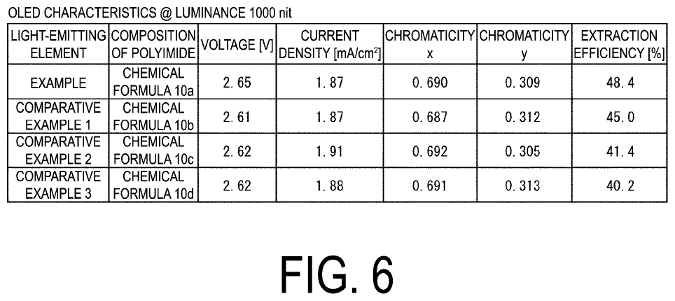

FIG. 6 is a table depicting a relationship between the light-emitting element according to Example, the light-emitting element according to Comparative Example 1, the light-emitting element according to Comparative Example 2 and the light-emitting element according to Comparative Example 3, and their light-emission characteristics. The definition of each column in FIG. 6 is as follows. From FIG. 6, it is understood that the light extraction efficiency to the outside from the light-emitting element according to Example is higher than the light extraction efficiency to the outside from the light-emitting element according to each of Comparative Examples 1 to 3.

Light-Emitting Element: the light-emitting element according to Example, the light-emitting element according to Comparative Example 1, the light-emitting element according to Comparative Example 2, and the light-emitting element according to Comparative Example 3.

Composition of Polyimide: Chemical Formulae 10a to 10d and their glass transition points Tg.

Voltage: drive voltage (unit: V).

Current Density: drive current density (unit: mA/cm²).

Chromaticity x: the value of x in the CIE XYZ colorimetric system.

Chromaticity y: the value of y in the CIE XYZ colorimetric system.

Extraction Efficiency: light extraction efficiency to the outside (unit: %).

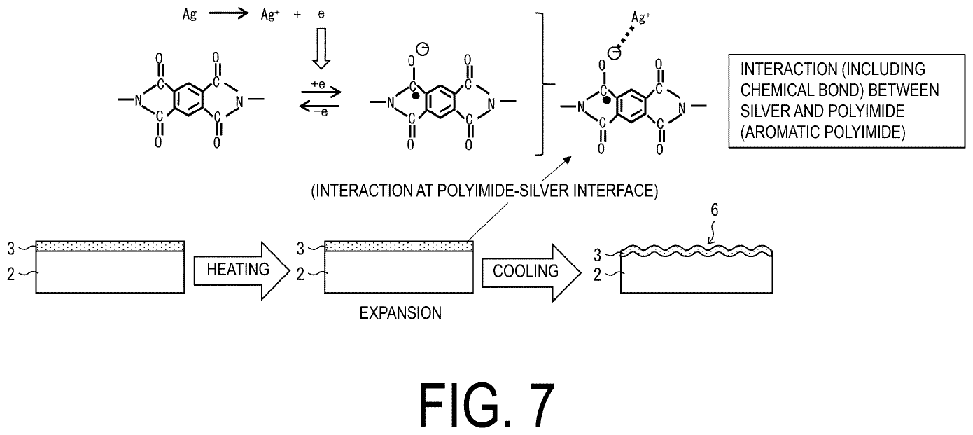

FIG. 7 is a diagram describing a chemical bond between silver contained in the reflective electrode 3 and polyimide constituting the insulating film 2 in the light-emitting element according to Example. FIG. 7 also describes cross-sectional shapes of the insulating film 2 and the reflective electrode 3 corresponding to stages of the chemical bond.

In the light-emitting element according to Example, the first protruding portion 6 is formed by the following mechanism in the fourth process of FIG. 3 described above. That is, due to the interaction between silver and an acid anhydride skeleton of polyimide, a chemical bond between polyimide and silver is formed when baking (heating in FIG. 7) is performed in the fourth process of FIG. 3. After completion of the fourth process of FIG. 3, the chemical bond is maintained even after the temperature of the insulating film 2 and the reflective electrode 3 is lowered to be less than the glass transition point of polyimide (cooling in FIG. 7). With this, silver is taken into the polyimide by the so-called anchoring effect, and the reflective electrode 3 being flat at the time point of completion of the third process of FIG. 3 shrinks in the fourth process of FIG. 3. As a result, in the manufacture of the light-emitting element according to Example, the first protruding portion 6 is formed in the fourth process of FIG. 3.

In the manufacture of the light-emitting element according to Comparative Example 1, since the glass transition point of polyimide used in the second process of FIG. 3 was significantly high, thermal expansion of the polyimide hardly occurred in the fourth process of FIG. 3. In the manufacture of each of the light-emitting element according to Comparative Example 2 and the light-emitting element according to Comparative Example 3, no chemical action was observed between polyimide and silver in the fourth process of FIG. 3. As a result, in the manufacture of each of the light-emitting element according to Comparative Example 1, the light-emitting element according to Comparative Example 2, and the light-emitting element according to Comparative Example 3, the first protruding portion 6 is not formed in the fourth process of FIG. 3.

As in the light-emitting element according to Example, in the light-emitting element 102, it is preferable that atoms contained in the insulating film 2 and atoms contained in the reflective electrode 3 be chemically bonded to each other. More specifically, in the light-emitting element 102, atoms contained in the insulating film 2 and atoms contained in the reflective electrode 3 are preferably bonded to each other based on any of an ionic bond, a dipole-dipole interaction, an ion-dipole interaction, van der Waals attraction, a coordination bond, a metal bond, and a hydrogen bond.

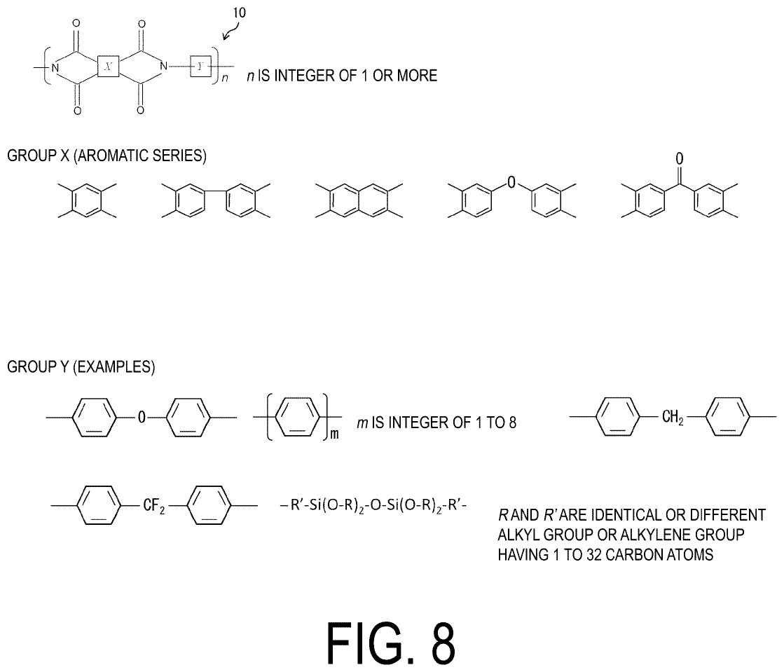

FIG. 8 is a diagram exemplifying a preferable composition of polyimide used in the second process of FIG. 3. The composition of the polyimide is represented by Chemical Formula 10. Examples of the compounds to be set in a blank X of Chemical Formula 10 include a compound listed in “Group X” in FIG. 8, but are not limited thereto. Examples of the compounds to be set in a blank Y of Chemical Formula 10 include a compound listed in “Group Y” in FIG. 8, but are not limited thereto. In Chemical Formula 10, it is sufficient that two imide groups interposing the blank X are bonded to each other by an aromatic ring (in other words, a site capable of being conjugated through x-electrons).

A light-emitting element according to Comparative Example 4 is a light-emitting element manufactured by the method for manufacturing the light-emitting element 102 illustrated in FIG. 3 except that the post-baking temperature in the second process of FIG. 3 is 260° C. In the manufacture of the light-emitting element according to Comparative Example 4, the composition of polyimide used in the second process of FIG. 3 is represented by Chemical Formula 10a in FIG. 5.

A light-emitting element according to Comparative Example 5 is a light-emitting element manufactured by the method for manufacturing the light-emitting element 102 illustrated in FIG. 3 except that the post-baking temperature in the second process of FIG. 3 is 260° C. and the glass transition point of polyimide used in the second process of FIG. 3 is 260° C. In the manufacture of the light-emitting element according to Comparative Example 5, the composition of the polyimide is represented by Chemical Formula 10b in FIG. 5.

In the manufacture of the light-emitting element according to Comparative Example 4, the first protruding portion 6 is formed in the fourth process of FIG. 3. Note that the height h1 (see FIG. 1) of the first protruding portion 6 of the light-emitting element according to Comparative Example 4 is smaller than the height h1 of the first protruding portion 6 of the light-emitting element according to Example, and is larger than 0 μm and equal to or less than 0.5 μm. In the manufacture of the light-emitting element according to Comparative Example 5, the first protruding portion 6 is not formed in the fourth process of FIG. 3.

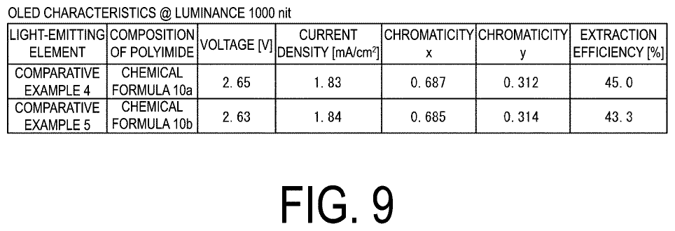

FIG. 9 is a table depicting a relationship between the light-emitting element according to Comparative Example 4 and the light-emitting element according to Comparative Example 5, and their light-emission characteristics. The definition of each column in FIG. 9 is similar to the definition of each column in FIG. 6. From FIG. 9, it is understood that the light extraction efficiency to the outside from the light-emitting element according to Comparative Example 4 is higher than the light extraction efficiency to the outside from the light-emitting element according to Comparative Example 5, but is lower than the light extraction efficiency to the outside from the light-emitting element according to Example.

A light-emitting element according to Comparative Example 6 is a light-emitting element manufactured by the method for manufacturing the light-emitting element 102 illustrated in FIG. 3 except that the baking temperature in the fourth process of FIG. 3 is 250° C. In the manufacture of the light-emitting element according to Comparative Example 6, the composition of polyimide used in the second process of FIG. 3 is represented by Chemical Formula 10a in FIG. 5.

In the manufacture of the light-emitting element according to Comparative Example 6, the first protruding portion 6 is formed in the fourth process of FIG. 3. Note that the height h1 (see FIG. 1) of the first protruding portion 6 of the light-emitting element according to Comparative Example 6 is larger than the height h1 of the first protruding portion 6 of the light-emitting element according to Example, and is 1.5 μm or more. In the light-emitting element according to Comparative Example 6, it was found that cracking occurred in the reflective electrode 3. An attempt to drive the light-emitting element according to Comparative Example 6 was made, but the light-emitting element according to Comparative Example 6 did not emit light.

As a reason why the light-emitting element according to Comparative Example 6 did not emit light, it is considered that the height h1 of the first protruding portion 6 was too large with respect to the film thickness of the EL layer 4 (usually in a range from about 100 nm to about 400 nm). That is, the following can be considered: the film thickness of each layer formed by vacuum vapor deposition in the fifth process of FIG. 3 was not uniform, and as a result, leakage occurred in the light-emitting element according to Comparative Example 6.

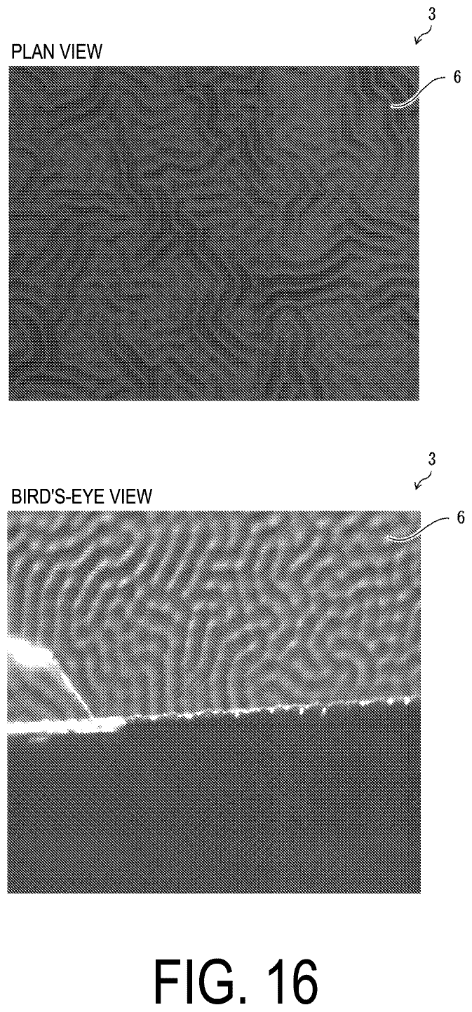

FIG. 16 provides a plan view and a bird's-eye view depicting a configuration example of the reflective electrode 3. As illustrated in FIG. 16, the shape of the first protruding portion 6 in a plan view of the light-emitting element corresponding to each embodiment and Example may be complex random wrinkles.

The light-emitting element 101 has a structure in which a thin film transistor layer and a light-emitting element layer are layered in this order. In the thin film transistor layer, a thin film transistor and the insulating film 2 formed of an organic material are laminated in this order. The thin film transistor is a TFT provided on the TFT substrate 1.

In other words, the thin film transistor layer has a layered structure of the TFT substrate 1 and the insulating film 2. In the light-emitting element layer, the reflective electrode 3 electrically connected to the thin film transistor and having light reflectivity, a light-emitting layer of the EL layer 4, and the translucent electrode 5 are layered in this order. In other words, the light-emitting element layer has a layered structure of the reflective electrode 3, the EL layer 4, and the translucent electrode 5. The reflective electrode 3 is provided on the insulating film 2, and the first protruding portion 6 is formed on the surface on the light-emitting layer side of the reflective electrode 3. A difference between the height of the highest point 6a of the first protruding portion 6 and the height of the lowest point 6b of the first protruding portion 6 in the film thickness direction D1 of the reflective electrode 3 is in a range from 0.4 μm to 1 μm.

The method for manufacturing the light-emitting element 102 is as follows: the insulating film 2 is formed by baking a polymer material, the reflective electrode 3 is formed on the insulating film 2, the reflective electrode 3 is baked, and the first protruding portion 6 having the height in the range from 0.4 μm to 1 μm is formed at least on the surface 3a of the reflective electrode 3 on the opposite side to the insulating film 2 by collectively baking the insulating film 2 and the reflective electrode 3 under vacuum.

### Second Embodiment

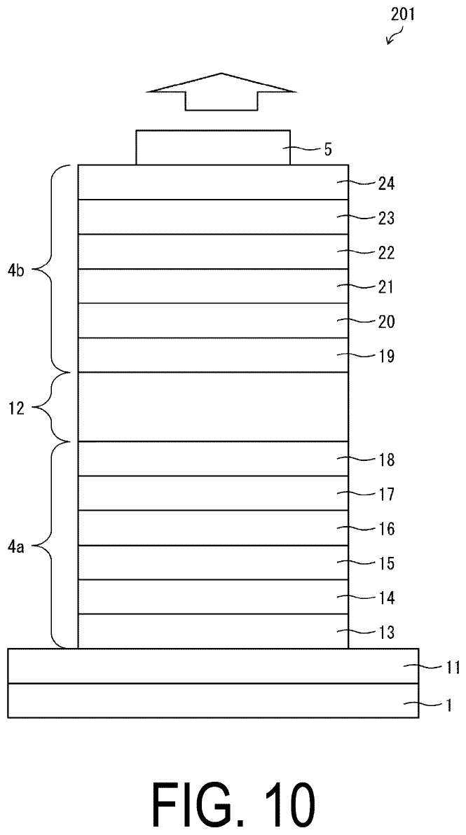

FIG. 10 is a cross-sectional view illustrating a schematic configuration of a light-emitting element 201 according to a second embodiment of the disclosure. The light-emitting element 201 includes a TFT substrate 1, an insulating film-cum-reflective electrode 11, a first EL layer 4a, a charge generation layer 12, a second EL layer 4b, and a translucent electrode 5. The insulating film-cum-reflective electrode 11 corresponds to a set of the insulating film 2 and the reflective electrode 3 in FIG. 1. Each of the first EL layer 4a and the second EL layer 4b corresponds to one EL layer 4 illustrated in FIG. 1. The TFT substrate 1, the insulating film-cum-reflective electrode 11, the first EL layer 4a, the charge generation layer 12, the second EL layer 4b, and the translucent electrode 5 are layered in this order. The light-emitting element 201 is a tandem light-emitting element including the charge generation layer 12.

The first EL layer 4a includes a hole injection layer 13, a first hole transport layer 14, a first electron blocking layer 15, a first light-emitting layer 16, a first hole blocking layer 17, and a first electron transport layer 18. The hole injection layer 13, the first hole transport layer 14, the first electron blocking layer 15, the first light-emitting layer 16, the first hole blocking layer 17, and the first electron transport layer 18 are layered in this order from the TFT substrate 1 side.

The second EL layer 4b includes a second hole transport layer 19, a second electron blocking layer 20, a second light-emitting layer 21, a second hole blocking layer 22, a second electron transport layer 23, and an electron injection layer 24. The second hole transport layer 19, the second electron blocking layer 20, the second light-emitting layer 21, the second hole blocking layer 22, the second electron transport layer 23, and the electron injection layer 24 are layered in this order from the TFT substrate 1 side.

The charge generation layer 12 is disposed between the first EL layer 4a and the second EL layer 4b; to put it more concisely, the charge generation layer 12 is disposed between the first light-emitting layer 16 and the second light-emitting layer 21.

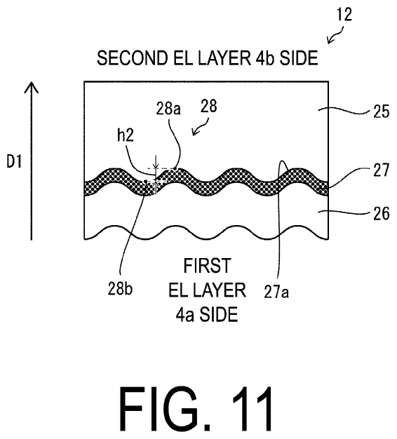

FIG. 11 is a cross-sectional view illustrating a configuration of the charge generation layer 12. The charge generation layer 12 includes a hole generation layer 25 configured to generate holes, an electron generation layer 26 configured to generate electrons, and an inorganic compound layer 27 disposed between the hole generation layer 25 and the electron generation layer 26. The electron generation layer 26, the inorganic compound layer 27, and the hole generation layer 25 are layered in this order from the TFT substrate 1 side.

The hole generation layer 25 is formed of a hole transport material (organic material) and an electron donor material (additive). The electron generation layer 26 is formed of an electron transport material (organic material). The inorganic compound layer 27 is formed of an inorganic compound capable of electron injection. The inorganic compound layer 27 is preferably formed of ytterbium or lithium.

The hole generation layer 25 can be formed by co-evaporation, for example, and the film thickness thereof is in a range from 10 nm to 15 nm, for example. The electron generation layer 26 can be formed by vapor deposition, for example, and the film thickness thereof is in a range from 10 nm to 15 nm, for example. The inorganic compound layer 27 can be formed by vapor deposition, for example, and the average film thickness thereof is in a range from 1 nm to 3 nm, for example.

A second protruding portion 28 is formed on a surface 27a on the hole generation layer 25 side of the inorganic compound layer 27. A height h2 of the second protruding portion 28 is preferably in a range from 0.4 μm to 1 μm, and more preferably in a range from 0.4 μm to 0.5 μm. As illustrated in FIG. 10 and FIG. 11, the height h2 of the second protruding portion 28 is defined by a difference between the height of a highest point 28a of the second protruding portion 28 and the height of a lowest point 28b of the second protruding portion 28 in the film thickness direction D1 of the reflective electrode 3. The second protruding portion 28 can be formed by leaving the inorganic compound layer 27 formed by vapor deposition for one hour at a temperature of 120° C. or higher under vacuum.

When the average film thickness of the inorganic compound layer 27 is in a range from 1 nm to 3 nm, it is possible to form irregularities having a height in a range from 0.4 μm to 1.5 μm. Instead of forming the inorganic compound layer 27, an inorganic compound capable of electron injection may be contained in the electron generation layer 26.

The light-emitting element 201 is a top-emitting type. Specifically, the light-emitting element 201 extracts light from the translucent electrode 5 side on the opposite side to the TFT substrate 1. The light-emitting element 201 is a tandem light-emitting element including the first light-emitting layer 16 and the second light-emitting layer 21. The first light-emitting layer 16 and the second light-emitting layer 21 may emit light of the same color or may emit light of different colors.

The light-emitting layer 16 and the second light-emitting layer 21 emit light by a current flowing between the reflective electrode 3 and the translucent electrode 5. Examples of the light-emitting layer 16 and the second light-emitting layer 21 include an OLED and a QLED. In the light-emitting element 201, the reflective electrode 3 is an anode electrode, and the translucent electrode 5 is a cathode electrode. The structure of the first EL layer 4a and the second EL layer 4b may be changed as appropriate in such a manner that the reflective electrode 3 serves as a cathode electrode and the translucent electrode 5 serves as an anode electrode.

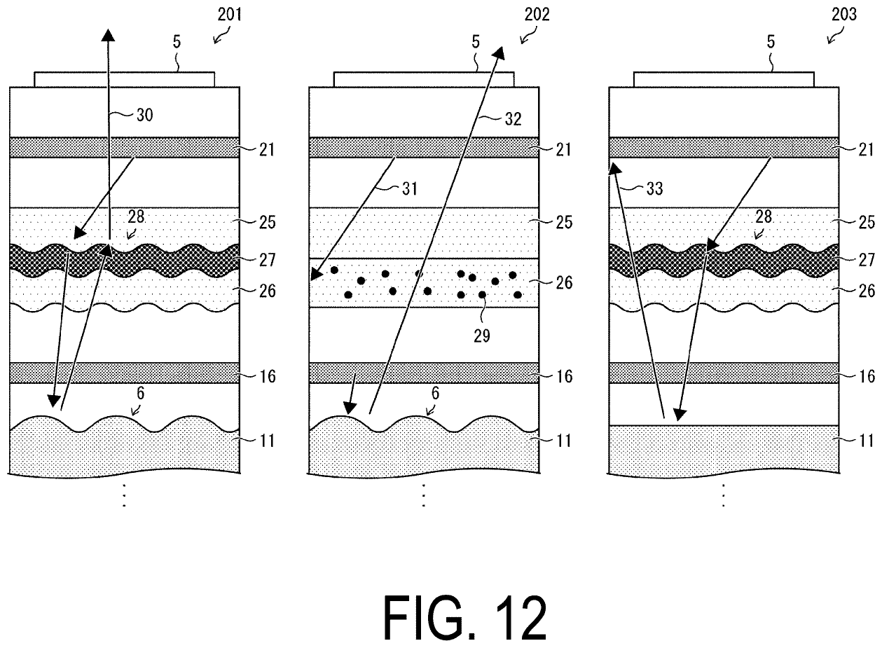

FIG. 12 is a diagram for comparing traveling paths of light in the light-emitting element 201, light in a light-emitting element 202 according to Comparative Example 7, and light in a light-emitting element 203 according to Comparative Example 8. Unlike the light-emitting element 201, the light-emitting element 202 does not have the inorganic compound layer 27 (including the second protruding portion 28), and instead contains an inorganic compound capable of electron injection (here, ytterbium 29) within the electron generation layer 26. Unlike the light-emitting element 201, the light-emitting element 203 does not have the first protruding portion 6 formed on the reflective electrode 3 of the insulating film-cum-reflective electrode 11.

In the light-emitting element 201, light 30 emitted by the second light-emitting layer 21 passes through the inorganic compound layer 27, is reflected by the insulating film-cum-reflective electrode 11 (the first protruding portion 6 of the reflective electrode 3), passes through the inorganic compound layer 27, and is emitted to the outside from the translucent electrode 5. As a result, in the light-emitting element 201, characteristics of light extraction from a color pixel end portion are preferable, and the light extraction efficiency to the outside is high.

In the light-emitting element 202, light 31 emitted by the second light-emitting layer 21 enters into a color pixel separation region (not illustrated) from a side surface of the light-emitting element 202. Since the color pixel separation region contains a photosensitive material or the like, the color pixel separation region absorbs most of the light 31 having entered thereinto. As a result, in the light-emitting element 202, it is difficult to extract the light 31 to the outside, and therefore the light extraction efficiency to the outside is low. On the other hand, in the light-emitting element 202, light 32 emitted by the first light-emitting layer 16 is reflected by the insulating film-cum-reflective electrode 11 (the first protruding portion 6 of the reflective electrode 3) and is emitted to the outside from the translucent electrode 5.

In the light-emitting element 203, light 33 emitted by the second light-emitting layer 21 enters into a color pixel separation region (not illustrated) from a side surface of the light-emitting element 203. As a result, it is difficult to extract the light 33 to the outside in the light-emitting element 203 based on a principle similar to the principle on which the light 31 is difficult to be extracted to the outside in the light-emitting element 202, and therefore the light extraction efficiency to the outside is low in the light-emitting element 203.

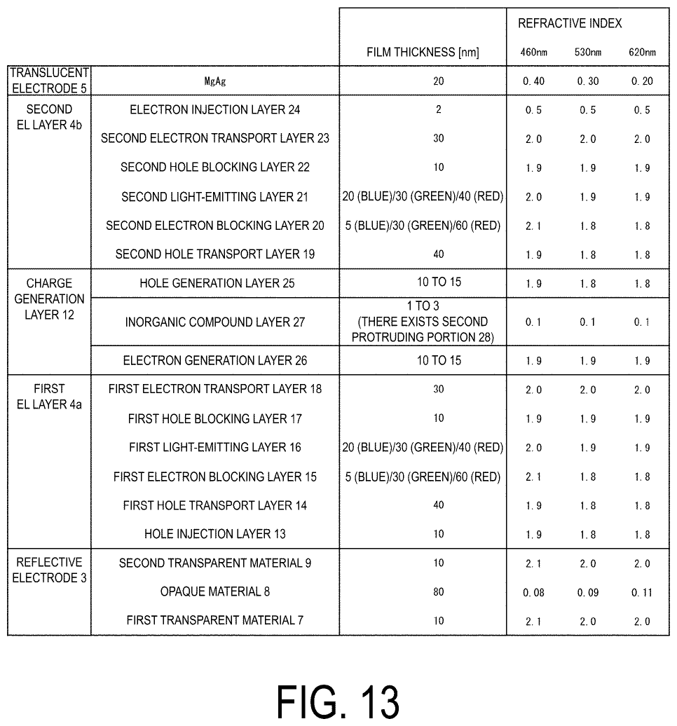

FIG. 13 is a table summarizing a film thickness and a refractive index of each layer of the light-emitting element 201. Since the film thickness of each of the first light-emitting layer 16 and the first electron blocking layer 15 of the first EL layer 4a varies depending on the colors (blue, green, and red) of light emitted by the first light-emitting layer 16, FIG. 13 specifically describes the correspondence between the colors of light emitted by the first light-emitting layer 16 and the film thicknesses. Since the film thickness of each of the second light-emitting layer 21 and the second electron blocking layer 20 of the second EL layer 4b varies depending on the colors (blue, green, and red) of light emitted by the second light-emitting layer 21, FIG. 13 specifically describes the correspondence between the colors of light emitted by the second light-emitting layer 21 and the film thicknesses. As for the refractive indices, a refractive index for 460 nm light (460 nm column), a refractive index for 530 nm light (530 nm column), and a refractive index for 620 nm light (620 nm column) are depicted.

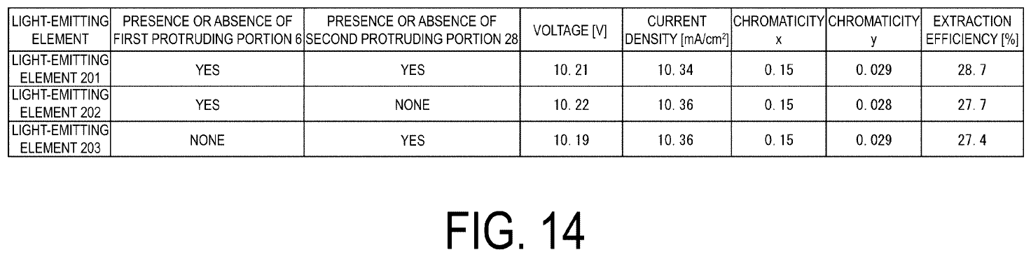

FIG. 14 is a table depicting a relationship between the light-emitting element 201, the light-emitting element 202 and the light-emitting element 203, and their light-emission characteristics. Among the columns in FIG. 14, a column with the same description as that of a column in FIG. 6 has the same definition as the corresponding column in FIG. 6. The definitions of the other columns in FIG. 14 are literal and therefore will not be described. From FIG. 14, it is understood that the light extraction efficiency to the outside from the light-emitting element 201 is higher than the light extraction efficiency to the outside from the light-emitting elements 202 and 203. The light extraction efficiency to the outside from the light-emitting element 201 is approximately 3.6% higher with respect to the light extraction efficiency to the outside from the light-emitting element 202.

The reasons why the light extraction efficiency to the outside from the light-emitting element 201 is high are summarized as described in the following (A) and (B).

(A) As depicted in FIG. 12, the light 30 can be extracted to the outside. In addition, in the light-emitting element 201, the light emitted by the first light-emitting layer 16 can be extracted to the outside based on substantially the same principle as the light 32.

(B) An inorganic compound capable of electron injection contained in the inorganic compound layer 27 generates electrons, and the generated electrons can be effectively transported to the first electron transport layer 18 through the electron generation layer 26.

### Third Embodiment

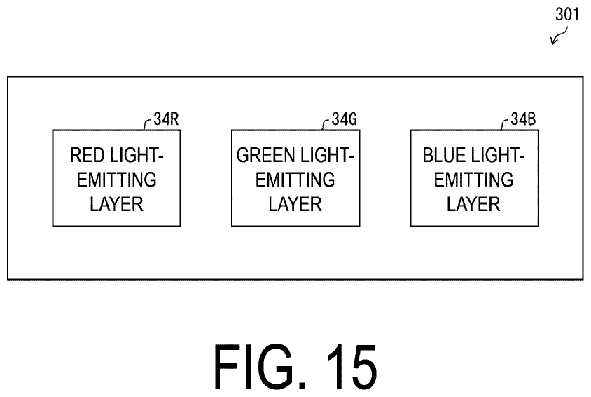

FIG. 15 is a block diagram illustrating a schematic configuration of a display device 301 according to a third embodiment of the disclosure. The display device 301 includes a red light-emitting layer 34R, a green light-emitting layer 34G, and a blue light-emitting layer 34B.

Each of the red light-emitting layer 34R, the green light-emitting layer 34G, and the blue light-emitting layer 34B may be formed by any of the light-emitting layer of the EL layer 4, the first light-emitting layer 16, and the second light-emitting layer 21 described above. Each of the red light-emitting layer 34R, the green light-emitting layer 34G, and the blue light-emitting layer 34B may be formed by an OLED or a QLED. In other words, the display device 301 may be an OLED display device or a QLED display device.

The display device 301 can be interpreted as a display device including at least one of the light-emitting element 101, the light-emitting element 102 or the light-emitting element 201, and having a high light extraction efficiency to the outside.

### Supplement

A light-emitting element according to a first aspect of the disclosure is a light-emitting element including a thin film transistor layer and a light-emitting element layer that are layered in this order. In the thin film transistor layer, a thin film transistor and an insulating film formed of an organic material are layered in this order. In the light-emitting element layer, a reflective electrode electrically connected to the thin film transistor and having light reflectivity, a light-emitting layer, and an electrode having optical transparency are layered in this order. The reflective electrode is provided on the insulating film, and a first protruding portion is formed on a surface on the light-emitting layer side of the reflective electrode. A difference between a height of the highest point of the first protruding portion and a height of the lowest point of the first protruding portion is in a range from 0.4 μm to 1 μm in a film thickness direction of the reflective electrode.

The light-emitting element according to a second aspect of the disclosure is such that, in the first aspect, a period of the first protruding portion in a direction perpendicular to the film thickness direction of the reflective electrode is in a range from 6 μm to 8 μm.

The light-emitting element according to a third aspect of the disclosure is such that, in the first or second aspect, a film thickness of the insulating film is in a range from 1 μm to 3 μm.

The light-emitting element according to a fourth aspect of the disclosure is such that, in any one of the first to third aspects, the insulating film is formed of a polymer material containing at least one of polyimide, polyamide, or polyamic acid.

The light-emitting element according to a fifth aspect of the disclosure is such that, in the fourth aspect, the polymer material is formed of only any one of polyimide, polyamide, and polyamic acid.

The light-emitting element according to a sixth aspect of the disclosure is such that, in the fourth or fifth aspect, a glass transition point of the polymer material is in a range from 110° C. to 210° C.

The light-emitting element according to a seventh aspect of the disclosure is such that, in any one of the first to sixth aspects, the reflective electrode has a layered structure of a first transparent material, an opaque material, and a second transparent material.

The light-emitting element according to an eighth aspect of the disclosure is such that, in the seventh aspect, the opaque material contains at least one of aluminum, silver, or magnesium.

The light-emitting element according to a ninth aspect of the disclosure is such that, in the seventh or eighth aspect, at least one of the first transparent material and the second transparent material contains ITO.

The light-emitting element according to a tenth aspect of the disclosure is a top-emitting light-emitting element and is also a tandem light-emitting element including a first light-emitting layer and a second light-emitting layer in any one of the first to ninth aspects.

The light-emitting element according to an eleventh aspect of the disclosure further includes, in the tenth aspect, a charge generation layer disposed between the first light-emitting layer and the second light-emitting layer, wherein the charge generation layer includes a hole generation layer configured to generate holes, an electron generation layer configured to generate electrons, and an inorganic compound layer disposed between the hole generation layer and the electron generation layer, a second protruding portion is formed on a surface on the hole generation layer side of the inorganic compound layer, and the height of the second protruding portion is in a range from 0.4 μm to 1 μm.

The light-emitting element according to a twelfth aspect of the disclosure is such that, in the eleventh aspect, the inorganic compound layer is formed of ytterbium or lithium.

The light-emitting element according to a thirteenth aspect of the disclosure is such that, in any one of the first to twelfth aspects, atoms included in the insulating film and atoms included in the reflective electrode are chemically bonded to each other.

The light-emitting element according to a fourteenth aspect of the disclosure is such that, in the thirteenth aspect, the atoms included in the insulating film and the atoms included in the reflective electrode are bonded to each other based on any of an ionic bond, a dipole-dipole interaction, an ion-dipole interaction, van der Waals attraction, a coordination bond, a metal bond, and a hydrogen bond.

A display device according to a fifteenth aspect of the disclosure includes the above-described light-emitting element.

A method for manufacturing a light-emitting element according to a sixteenth aspect of the disclosure includes: forming an insulating film by baking a polymer material; forming a reflective electrode on the insulating film; baking the reflective electrode; and forming a protruding portion having a height in a range from 0.4 μm to 1 μm at least on a surface of the reflective electrode on the opposite side to the insulating film by collectively baking the insulating film and the reflective electrode under vacuum.

The method for manufacturing the light-emitting element according to a seventeenth aspect of the disclosure is such that, in the sixteenth aspect, the baking of each of the polymer material and the reflective electrode is performed at a temperature lower than a glass transition point of the polymer material.

The method for manufacturing the light-emitting element according to an eighteenth aspect of the disclosure is such that, in the sixteenth or seventeenth aspect, the polymer material is formed of only any one of polyimide, polyamide, and polyamic acid.

The method for manufacturing the light-emitting element according to a nineteenth aspect of the disclosure is such that, in any one of the sixteenth to eighteenth aspects, a glass transition point of the polymer material is in a range from 110° C. to 210° C.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting element comprising:
a thin film transistor layer and a light-emitting element layer that are layered in this order,
wherein in the thin film transistor layer, a thin film transistor and an insulating film formed of an organic material are layered in this order,
in the light-emitting element layer, a reflective electrode electrically connected to the thin film transistor and having light reflectivity, a light-emitting layer, and an electrode having optical transparency are layered in this order,
the reflective electrode is provided on the insulating film, and a first protruding portion is formed on a surface on the light-emitting layer side of the reflective electrode, and
a difference between a height of a highest point of the first protruding portion and a height of a lowest point of the first protruding portion is in a range from 0.4 μm to 1 μm in a film thickness direction of the reflective electrode.

2. The light-emitting element according to claim 1,
wherein a period of the first protruding portion in a direction perpendicular to the film thickness direction of the reflective electrode is in a range from 6 μm to 8 μm.

3. The light-emitting element according to claim 1,
wherein a film thickness of the insulating film is in a range from 1 μm to 3 μm.

4. The light-emitting element according to claim 1,
wherein the insulating film is formed of a polymer material containing at least one of polyimide, polyamide, or polyamic acid.

5. The light-emitting element according to claim 4,
wherein the polymer material is formed of only any one of polyimide, polyamide, and polyamic acid.

6. The light-emitting element according to claim 4,
wherein a glass transition point of the polymer material is in a range from 110° C. to 210° C.

7. The light-emitting element according to claim 1,
wherein the reflective electrode has a layered structure of a first transparent material, an opaque material, and a second transparent material.

8. The light-emitting element according to claim 7,
wherein the opaque material contains at least one of aluminum, silver, and magnesium.

9. The light-emitting element according to claim 7,
wherein at least one of the first transparent material and the second transparent material contains ITO.

10. The light-emitting element according to claim 1,
wherein the light-emitting element is a top-emitting light-emitting element and is also a tandem light-emitting element including a first light-emitting layer and a second light-emitting layer.

11. The light-emitting element according to claim 10, further comprising:
a charge generation layer disposed between the first light-emitting layer and the second light-emitting layer,
wherein the charge generation layer includes a hole generation layer configured to generate holes, an electron generation layer configured to generate electrons, and an inorganic compound layer disposed between the hole generation layer and the electron generation layer,
a second protruding portion is formed on a surface on the hole generation layer side of the inorganic compound layer, and
a height of the second protruding portion is in a range from 0.4 μm to 1 μm.

12. The light-emitting element according to claim 11,
wherein the inorganic compound layer is formed of ytterbium or lithium.

13. The light-emitting element according to claim 1,
wherein atoms included in the insulating film and atoms included in the reflective electrode are chemically bonded to each other.

14. The light-emitting element according to claim 13,
wherein the atoms included in the insulating film and the atoms included in the reflective electrode are bonded to each other based on any of an ionic bond, a dipole-dipole interaction, an ion-dipole interaction, van der Waals attraction, a coordination bond, a metal bond, and a hydrogen bond.

15. A display device comprising:
the light-emitting element according to claim 1.

16-19. (canceled)
